(19) United States
(12) Patent Application Publication
(10) Pub. No.: US 2026/0082592 A1
(43) Pub. Date: Mar. 19, 2026

(54) SEMICONDUCTOR PACKAGE

(71) Applicant: Samsung Electronics Co., Ltd., Suwon-si (KR)

(72) Inventors: Taejun JEON, Suwon-si (KR); Yonghyun KIM, Suwon-si (KR); Wonil SEO, Suwon-si (KR)

(73) Assignee: Samsung Electronics Co., Ltd., Suwon-si (KR)

(21) Appl. No.: 19/228,181

(22) Filed: Jun. 4, 2025

(30) Foreign Application Priority Data
Sep. 13, 2024 (KR) 10-2024-0125316

(51) Int. Cl. H10B 80/00; H10W 72/00; H10W 72/30; H10W 72/50; H10W 74/10; H10W 90/00; H10W 90/20; H10W 90/24

(52) U.S. Cl. CPC H10B 80/00; H10W 90/00; H10W 72/073; H10W 72/07353; H10W 72/07354; H10W 72/322; H10W 72/334; H10W 72/347; H10W 72/5473; H10W 72/884; H10W 74/111; H10W 90/20; H10W 90/24; H10W 90/734; H10W 90/752; H10W 90/754

(57) ABSTRACT

A semiconductor package may include a substrate including an upper surface including a first upper pad; first semiconductor chips stacked on the substrate; and a first controller structure in contact with a side surface of at least one of the first semiconductor chips. The first controller structure may include a first controller chip, a first insulating film, and a first conductive film. A first surface of the first controller chip may face a first horizontal direction and may include a first contact pad disposed thereon. The first insulating film may expose the first contact pad and may extend along the first surface of the first controller chip to the substrate. The first conductive film may cover the first contact pad of the first controller chip and the first upper pad of the substrate.

### CROSS-REFERENCE TO RELATED APPLICATION(S)

This application claims benefit of priority to Korean Patent Application No. 10-2024-0125316, filed on Sep. 13, 2024 in the Korean Intellectual Property Office, the disclosure of which is incorporated herein by reference in its entirety.

### BACKGROUND

Example embodiments of the present disclosure relate to a semiconductor package, more particularly, a semiconductor package including a controller chip.

In order to expand capacity and/or a function of a semiconductor package, integration density in a wafer state has been gradually increased, and a semiconductor package integrated with two or more chips or other semiconductor packages has also been common.

Among the integrated semiconductor packages, a package in which two or more semiconductor chips are integrated has been used. As an example of a multi-chip package, a structure in which a plurality of memory chips are stacked on a substrate, and a controller chip may be disposed to control operation of the plurality of memory chips. The memory chips, the substrate, and the controller substrate may be electrically connected to each other through wires.

### SUMMARY

An example embodiment of the present disclosure is to provide a semiconductor package having improved integration density.

According to an example embodiment of the present disclosure, a semiconductor package may include a substrate including a first pad and a second pad spaced apart from each other on an upper surface of the substrate; a first chip structure including first semiconductor chips stacked in order on the substrate and having a staircase shape in a first horizontal direction, the first semiconductor chips including a first intermediate semiconductor chip having an upper surface spaced apart from the upper surface of the substrate by a first height; a second chip structure including second semiconductor chips stacked in order on the substrate to have a staircase shape in a second horizontal direction, the second horizontal direction being opposite the first horizontal direction, the second semiconductor chips including a second intermediate semiconductor chip having an upper surface spaced apart from the upper surface of the substrate by the first height; and a first controller structure on a first side surface of the first intermediate semiconductor chip. The first controller structure may include a first controller chip, a first insulating film, and a first conductive film. A first surface of the first controller chip may face the first horizontal direction and may include a first contact pad disposed thereon. A second surface of the first controller chip may be opposite the first surface of the first controller chip. The first insulating film may extend along the first surface of the first controller chip to the substrate and may expose the first contact pad. The first conductive film may be on the first insulating film and may cover the first contact pad of the first controller chip and the first pad of the substrate.

According to an example embodiment of the present disclosure, a semiconductor package may include a substrate including an upper surface including a first upper pad; first semiconductor chips stacked in order on the substrate; and a first controller structure in contact with a side surface of at least one semiconductor chip among the first semiconductor chips. The first controller structure may include a first controller chip, a first insulating film, and a first conductive film. A first surface of the first controller chip may face a first horizontal direction and may include a first contact pad disposed thereon. A second surface of the first controller chip may be opposite the first surface of the first controller chip. The first insulating film may expose the first contact pad and may extend along the first surface of the first controller chip to the substrate. The first conductive film may be on the first insulating film and may cover the first contact pad of the first controller chip and the first upper pad of the substrate.

According to an example embodiment of the present disclosure, a semiconductor package may include a substrate having a first side surface, a second side spaced apart from the first side surface in a horizontal direction, and an upper surface including a first pad disposed thereon; first semiconductor chips stacked in order on the substrate so as to have a staircase shape adjacent to the first side surface; and a first controller structure on the substrate and overlapping a portion of the first semiconductor chips in a vertical direction. The vertical direction may intersect the horizontal direction. The first controller structure may include a first controller chip, a first insulating film, and a first conductive film. The first controller chip may extend perpendicular to the upper surface of the substrate. A first surface of the first controller chip may be adjacent to the first side surface of the substrate and may include a first contact pad disposed thereon. A second surface of the first controller chip may be opposite the first surface of the first controller chip. The first insulating film may extend onto the substrate from a location of the first surface of the first controller chip that is below the first contact pad. The first conductive film may be on the first insulating film and may cover the first contact pad and the first pad of the substrate.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a cross-sectional diagram illustrating a semiconductor package according to example embodiments of the present disclosure;

FIG. 2 is a cross-sectional diagram illustrating the semiconductor package illustrated in FIG. 1 according to an example embodiment of the present disclosure;

FIG. 3 is a diagram illustrating region A of the semiconductor package illustrated in FIG. 2 according to an example embodiment of the present disclosure;

FIG. 4 is a diagram illustrating a first controller structure in FIG. 1 according to an example embodiment of the present disclosure, viewed from side;

FIG. 5 is a cross-sectional diagram illustrating a semiconductor package taken along line I-I′ according to another example embodiment of the present disclosure;

FIG. 6 is a cross-sectional diagram illustrating a semiconductor package taken along line I-I′ according to another example embodiment of the present disclosure;

FIG. 7 is an enlarged diagram illustrating region B of the semiconductor package illustrated in FIG. 6 according to an example embodiment of the present disclosure;

FIG. 8 is a cross-sectional diagram illustrating a semiconductor package according to another example embodiment of the present disclosure;

FIG. 9 is a cross-sectional diagram illustrating a semiconductor package according to another example embodiment of the present disclosure;

FIG. 10 is a cross-sectional diagram illustrating the semiconductor package illustrated in FIG. 9 taken along line II-II′ according to an example embodiment of the present disclosure;

FIG. 11 is a cross-sectional diagram illustrating the semiconductor package illustrated in FIG. 9 taken along line III-III′ according to an example embodiment of the present disclosure; and

FIGS. 12A to 12E are cross-sectional diagrams illustrating a semiconductor package according to an example embodiment of the present disclosure.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, embodiments of the present disclosure will be described as follows with reference to the accompanying drawings.

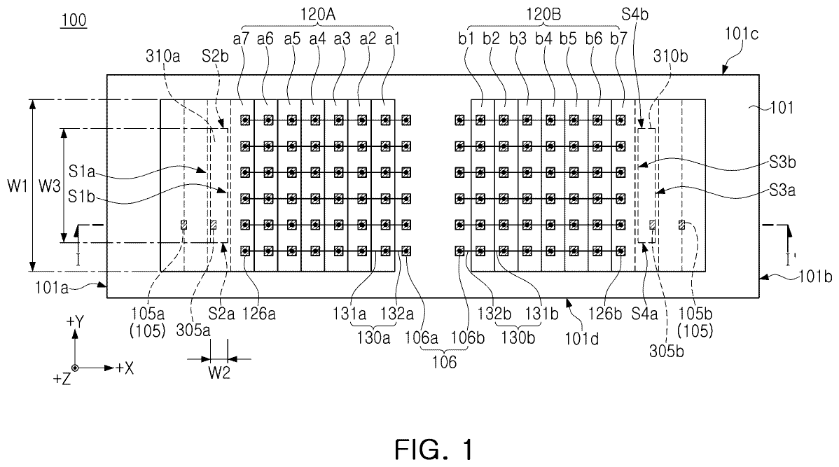

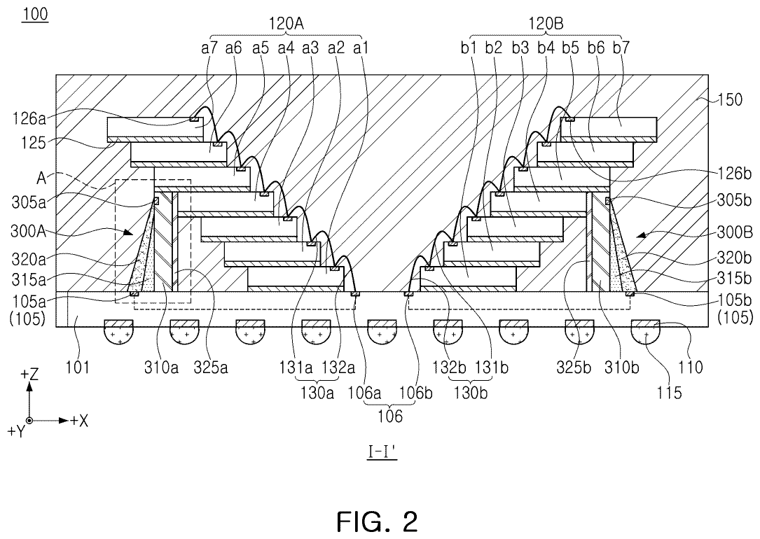

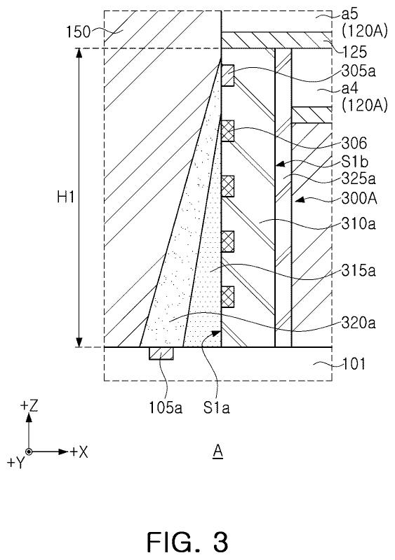

FIG. 1 is a cross-sectional diagram illustrating a semiconductor package according to example embodiments. FIG. 2 is a cross-sectional diagram illustrating the semiconductor package illustrated in FIG. 1 according to an example embodiment. FIG. 3 is a diagram illustrating region A of the semiconductor package illustrated in FIG. 2 according to an example embodiment.

Referring to FIGS. 1, 2, and 3, the semiconductor package 100 may include a substrate 101, first and second chip structures 120A and 120B on the substrate 101, first and second controller structures 300A and 300B, and first and second bonding wire structures 130a and 130b for electrically connecting the first and second chip structures 120A and 120B to the substrate 101. The semiconductor package 100 may further include an encapsulant 150 for encapsulating the first and second chip structures 120A and 120B and the first and second controller structures 300A and 300B on the substrate 101.

The substrate 101 may include an upper surface and a lower surface opposing the upper surface. The substrate 101 may be implemented as a support substrate on which the first and second chip structures 120A and 120B and first and second controller structures 300A and 300B are mounted on the upper surface of the substrate 101, and may be configured as a semiconductor package substrate including a printed circuit substrate (PCB), a ceramic substrate, a glass substrate, a tape interconnection substrate, or the like. In an example, the substrate 101 may include different materials depending on the type of the substrate. For example, when the substrate 101 is implemented as a printed circuit substrate, an interconnection layer may be further stacked on one side or both sides. In an example, a solder resist layer may be disposed on a lower surface and an upper surface of the substrate 101.

The substrate 101 may include a first side surface 101a adjacent to the first chip structure 120A, a second side surface 101b adjacent to the second chip structure 120B and spaced apart from the first side surface 101a in the +X-direction, a third side surface 101c intersecting the first side surface 101a and the second side surface 101b, and a fourth side surface 101d opposing the third side surface 101c. The first side surface 101a and the second side surface 101b may extend in the +Y-direction, and the third side surface 101c and the fourth side surface 101d may extend in the +X-direction.

The substrate 101 may include first and second upper pads 105 and 106 disposed on the upper surface and lower pads 110 disposed on the lower surface of the substrate 101. The first and second upper pads 105 and 106 may be buried in the substrate 101, and upper surfaces of the first and second upper pads 105 and 106 may be coplanar with the upper surface of the substrate 101. The lower pads 110 may be buried in the substrate 101, and a lower surface of the lower pads 110 may be coplanar with the lower surface of the substrate 101.

The first upper pads 105 may include the first and second pads 105a and 105b. The first upper pads 105 may be connection pads for electrically connecting the first and second controller chips 310a and 310b described below and the substrate 101. In an example, the first pad 105a may be a connection pad for connecting the first controller chip 310a to the substrate 101, and the second pad 105b may be a connection pad for connecting the second controller chip 310b to the substrate 101. In an example, the first pad 105a may overlap the first chip structure 120A in the third direction (Z-direction), and the second pad 105b may overlap the second chip structure 120B in the third direction (Z-direction). For example, the first pad 105a may overlap a 1-6 semiconductor chip a6 in the third direction (Z-direction), and the second pad 105b may overlap a 2-6 semiconductor chip b6 in the third direction (Z-direction).

The second upper pads 106 may be disposed apart from the first upper pads 105, and may include third and fourth pads 106a and 106b. The second upper pads 106 may be configured as connection pads for electrically connecting the first and second chip structures 120A and 120B to the substrate 101 described below. In an example, the third pad 106a may be configured as a connection pad for connecting the first chip structure 120A to the substrate 101, and the fourth pad 106b may be a connection pad for connecting the second chip structure 120B to the substrate 101. The third pads 106a may be arranged adjacently to the first chip structure 120A in the second horizontal direction (+X-direction) and may be spaced apart from each other in the second direction (Y-direction). The fourth pads 106b may be arranged adjacently to the second chip structure 120B in the first horizontal direction (−X-direction) and may be spaced apart from each other in the second direction (Y-direction).

In an example, a spacing between the third and fourth pads 106a and 106b may be smaller than a spacing between the first and second pads 105a and 105b. In an example, the first and second chip structures 120A and 120B and the third and fourth pads 106a and 106b may be disposed between the first and second pads 105a and 105b. The third and fourth pads 106a and 106b may be disposed between the first and second chip structures 120A and 120B.

The external connection terminals 115 may be disposed on a lower surface of the lower pads 110. The external connection terminals 115 may be, for example, solder balls or bumps. The external connection terminals 115 may electrically connect the semiconductor package 100 to an external electronic device.

The first and second upper pads 105 and 106 and the lower pads 110 may include at least one metal or an alloy of two or more metals selected from a group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C). The external connection terminals 115 may include, for example, tin (Sn) or an alloy including tin (Sn) (e.g., Sn—Ag—Cu).

A plurality of interconnection structures (not illustrated) (or interconnection circuits) connecting the first and second upper pads 105 and 106 to the lower pads 110 may be disposed. The interconnection structure may include interconnection lines and connection vias connecting the interconnection lines to each other.

In example embodiments, the first direction may indicate the X-direction, the second direction intersecting the first direction (X-direction) may indicate the Y-direction, and the third direction (or vertical direction) intersecting the first direction (X-direction) and the second direction (Y-direction) may indicate the Z-direction. The first direction (X-direction) may include the first horizontal direction (+X-direction) and the second horizontal direction (−X-direction) opposite to the first horizontal direction (+X-direction). The second direction (Y-direction) may include the third horizontal direction (+Y-direction) and a fourth horizontal direction (−Y-direction) opposite to the third horizontal direction (+Y-direction).

A first chip structure 120A and a second chip structure 120B spaced apart from the first chip structure 120A in the second horizontal direction (+X-direction) may be disposed on the substrate 101.

The first chip structure 120A may include first semiconductor chips a1-a7 stacked in order in a staircase shape in the first horizontal direction (−X-direction) on the substrate 101. Each of the first semiconductor chips a1-a7 may be shifted from each other in the first horizontal direction (−X-direction) by a first distance and may be stacked in order. First chip pads 126a may be disposed on an exposed upper surface of each of the first semiconductor chips a1-a7. The first chip pads 126a may be arranged in a staircase shape in the first horizontal direction (−X-direction). An adhesive film 125 may be disposed in a lower portion of each of the first semiconductor chips a1-a7 such that the first chip structure 120A may be attached to the upper surface of the substrate 101.

The first semiconductor chips a1-a7 may include a 1-1 semiconductor chip a1, a 1-2 semiconductor chip a2, a 1-3 semiconductor chip a3, a 1-4 semiconductor chip a4, a 1-5 semiconductor chip a5, a 1-6 semiconductor chip a6, and a 1-7 semiconductor chip a7 stacked in order. In an example, the 1-1 semiconductor chip a1 may be referred to as a lowermost semiconductor chip of the first chip structure 120A, and the 1-7 semiconductor chip a7 may be referred to as an uppermost semiconductor chip of the first chip structure 120A. The 1-2 semiconductor chip a2, the 1-3 semiconductor chip a3, the 1-4 semiconductor chip a4, the 1-5 semiconductor chip a5, and the 1-6 semiconductor chip a6 may be referred to as intermediate semiconductor chips. In an example, the first semiconductor chips a1-a7 may be configured as seven chips, but an example embodiment thereof is not limited thereto, and the first semiconductor chips a1-a7 may include eight or more chips or three or more and six or fewer chips.

The first bonding wire structure 130a may include a first upper wire structure 131a connecting the first chip pads 126a to each other and a first lower wire structure 132a connecting the first chip structure 120A to the substrate 101. In an example, the first upper wire structure 131a may connect the first chip pads 126a disposed on upper surfaces of the 1-1 semiconductor chip a1 to the 1-7 semiconductor chip a7. The first lower wire structure 132a may connect the first chip pad 126a to the third pad 106a of the 1-1 semiconductor chip a1.

The second chip structure 120B may include second semiconductor chips b1-b7 spaced apart from the first chip structure 120A in the second horizontal direction (+X-direction) on the substrate 101, may have a staircase shape in the second horizontal direction (+X-direction) and may be stacked in order. Each of the second semiconductor chips b1-b7 may be shifted from each other in the second horizontal direction (+X-direction) by the first distance and may be stacked in order. Second chip pads 126b may be disposed on an exposed upper surface of each of the second semiconductor chips b1-b7. The second chip pads 126b may be arranged in the staircase shape in the second horizontal direction (+X-direction). An adhesive film 125 may be disposed in a lower portion of each of the second semiconductor chips b1-b7 such that the second chip structure 120B may be attached to an upper surface of the substrate 101.

Each of the second semiconductor chips b1-b7 may include a 2-1 semiconductor chip b1, a 2-2 semiconductor chip b2, a 2-3 semiconductor chip b3, a 2-4 semiconductor chip b4, a 2-5 semiconductor chip b5, a 2-6 semiconductor chip b6, and a 2-7 semiconductor chip b7 shifted from each other in the second horizontal direction (+X-direction) by the first distance and stacked in order. In an example, the 2-1 semiconductor chip b1 may be referred to as a lowermost semiconductor chip of the second chip structure 120B, and the 2-7 semiconductor chip b7 may be referred to as an uppermost semiconductor chip of the second chip structure 120B. The 2-2 semiconductor chip b2, the 2-3 semiconductor chip b3, the 2-4 semiconductor chip b4, the 2-5 semiconductor chip b5, and the 2-6 semiconductor chip b6 may be referred to as intermediate semiconductor chips. In an example, the second semiconductor chips b1-b7 may include seven chips similarly to the first semiconductor chips a1-a7, but an example embodiment thereof is not limited thereto, and the second semiconductor chips b1-b7 may include eight or more chips or three or more and six or fewer chips.

The second bonding wire structure 130b may include a second upper wire structure 131b connecting the second chip pads 126b to each other and a second lower wire structure 132b connecting the second chip structure 120B to the substrate 101. In an example, the second upper wire structure 131b may connect the second chip pads 126b disposed on upper surfaces of the 2-1 semiconductor chip b1 to the 2-7 semiconductor chip b7 to each other, respectively. The second lower wire structure 132b may connect the second chip pad 126b to the fourth pad 106b of the 2-1 semiconductor chip b1.

The first controller structure 300A may be disposed on the substrate 101 and may overlap a portion of the first chip structure 120A in the vertical direction (Z-direction). The first controller structure 300A may be disposed on one side of one of the intermediate semiconductor chips of the first chip structure 120A, adjacent to the first side surface 101a of the substrate 101. For example, the first controller structure 300A may be disposed on one side of the 1-4 semiconductor chip a4 of the first chip structure 120A, adjacent to the first side surface 101a of the substrate 101. In this case, the first intermediate semiconductor chip may be the 1-4 semiconductor chip a4. The first controller structure 300A may be in contact with one side of the 1-4 semiconductor chip a4, adjacent to the first side surface 101a of the substrate 101.

The first chip structure 120A may have staircase surfaces shifted from each other by a desired and/or alternatively predetermined distance in the first horizontal direction (−X-direction), and the first controller structure 300A may be disposed to overlap the staircase surface of the first chip structure 120A in the third direction (Z-direction). The second surface S1b of the first chip structure 120A may be spaced apart from one side of the 1-1 semiconductor chip a1, one side of the 1-2 semiconductor chip a2, and one side of the 1-3 semiconductor chip a3, adjacent to the first side surface 101a, in the second horizontal direction (+X-direction).

The first controller structure 300A may include a first controller chip 310a having a first surface S1a on which a first contact pad 305a is disposed, a first insulating film 315a disposed on a portion of the first surface S1a of the first controller chip 310a, and a first conductive film 320a covering the first contact pad 305a and the first pad 105a of the substrate 101 on the first insulating film 315a. The first controller structure 300A may further include a first adhesive film 325a disposed on a second surface S1b of the first controller chip 310a.

The first controller chip 310a may include a control circuit for the first chip structure 120A. The first controller chip 310a may include a memory controller configured to determine a data processing order of a plurality of memory chips and to limit and/or prevent errors and bad sectors. The first controller chip 310a may be electrically connected to the substrate 101 through the first conductive film 320a connecting the first contact pad 305a to the first pad 105a.

The first controller chip 310a may include a first surface S1a oriented in the first horizontal direction (−X-direction), a second surface S1b opposite the first surface S1a and oriented in the second horizontal direction (+X-direction), a third surface S2a oriented in the fourth horizontal direction (−Y-direction), and a fourth surface S2b opposite the third surface S2a and oriented in the third horizontal direction (+Y-direction). In an example, an area of each of the first surface S1a and the second surface S1b may be larger than an area of a lower surface and an upper surface of each of the third surface S2a, the fourth surface S2b, and the first controller chip 310a.

The first controller chip 310a may have a first horizontal length W2 in the first direction (X-direction), a second horizontal length W3 in the second direction (Y-direction), and a vertical length H1 in the third direction (Z-direction). The first horizontal length W2 of the first controller chip 310a may be smaller than the second horizontal length W3 and the vertical length H1. The first horizontal length W2 of the first controller chip 310a may be smaller than the first distance between the first semiconductor chips a1-a7. However, but an example embodiment thereof is not limited thereto, and in another example, the first horizontal length W2 of the first controller chip 310a may be substantially equal to the first distance between the first semiconductor chips a1-a7. In an example, the second horizontal length W3 of the first controller chip 310a may be smaller than the length W1 of the first chip structure 120A in the second direction (Y-direction). However, but an example embodiment thereof is not limited thereto, and in another example, the second horizontal length W3 of the first controller chip 310a may be substantially the same as the length W1 of the first chip structure 120A in the second direction (Y-direction).

An upper surface of the first controller chip 310a may be disposed at the same level as an upper surface of the 1-4 semiconductor chip a4 in contact with the first controller structure 300A, or may be disposed at a level lower than a level of the upper surface of the 1-4 semiconductor chip a4. An upper surface of the first controller chip 310a may be disposed at a level higher than a level of an upper surface of the 1-3 semiconductor chip a3. In an example, when the upper surface of the first controller chip 310a is disposed at the same level as the upper surface of the 1-4 semiconductor chip a4, the upper surface of the first controller chip 310a may be in contact with a lower surface of the adhesive film 125 disposed on a lower surface of the 1-5 semiconductor chip a5.

The first contact pad 305a may be disposed on the first surface S1a of the first controller chip 310a and may be buried in the first controller chip 310a. The first contact pad 305a may be disposed in an upper region of the first surface S1a. In an example, the first contact pad 305a may be electrically connected to the first pad 105a on the substrate 101 via the first conductive film 320a. When viewed on a plane, the first contact pad 305a and the first pad 105a may be disposed on a conceptual axis parallel to the first direction (X-direction).

The first insulating film 315a may cover a lower region disposed below a region in which the first contact pad 305a is disposed on the first surface S1a of the first controller chip 310a, may extend to the substrate 101, and may extend to a region adjacent to the first pad 105a on the substrate 101. The first contact pad 305a of the first surface S1a and the first pad 105a of the substrate 101 may be exposed from the first insulating film 315a. In an example, the first insulating film 315a may cover pads 306 on the first surface S1a of the first controller chip 310a and may limit and/or prevent the pads 306 from being electrically shorted. In an example, the first insulating film 315a may have a width increasing downwardly in the first direction (X-direction). For example, a lowermost width of the first insulating film 315a in contact with the substrate 101 may be about 5 μm. In an example, the first insulating film 315a may include an insulating material including an epoxy resin, a solder resist material, or a photosensitive resin material.

A first conductive film 320a covering the first contact pad 305a of the first controller chip 310a and the first pad 105a of the substrate 101 may be disposed on the first insulating film 315a. The first controller chip 310a and the substrate 101 may be electrically connected to each other through the first conductive film 320a. The first conductive film 320a may cover the first contact pad 305a on the first surface S1a of the first controller chip 310a, may extend to the first insulating film 315a and may cover the first pad 105a on the substrate 101. The first conductive film 320a disposed on the first insulating film 315a may correspond to a surface profile of the first insulating film 315a. The first conductive film 320a may have a thickness in the first direction (X-direction), increasing toward the upper surface of the substrate 101. The first conductive film 320a may include a conductive material, for example, at least one metal among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C), or an alloy including two or more metals.

The first adhesive film 325a may be disposed on the second surface S1b of the first controller chip 310a. However, an example embodiment thereof is not limited thereto, and the first adhesive film 325a may be omitted. In an example, the first adhesive film 325a may be in contact with a side surface oriented in the first horizontal direction (−X-direction) of the 1-4 semiconductor chip a4. The first adhesive film 325a may include an adhesive film such as a direct adhesive film (DAF).

The first controller structure 300A may overlap the 1-4 semiconductor chip a4 to the 1-7 semiconductor chip a7 in the third direction (Z-direction).

The second controller structure 300B may be disposed on the substrate 101 and may overlap a portion of the second chip structure 120B in the vertical direction (Z-direction). The second controller structure 300B may be disposed adjacent to the second side surface 101b of the substrate 101 and may be disposed on one side of one of the intermediate semiconductor chips of the second chip structure 120B. In an example, the second controller structure 300B may be disposed on one side of the 2-4 semiconductor chip b4 of the second chip structure 120B adjacent to the second side surface 101b of the substrate 101. In this case, the second intermediate semiconductor chip may be the 2-4 semiconductor chip b4.

In the second chip structure 120B, the second semiconductor chips b1-b7 may have staircase surfaces shifted from each other by a desired and/or alternatively predetermined distance in the second horizontal direction (+X-direction), and the second controller structure 300B may overlap the staircase surface of the second chip structure 120B in the third direction (Z-direction).

The second controller structure 300B may include a second controller chip 310b having a first surface S3a on which a second contact pad 305b is disposed, a second insulating film 315b disposed on a portion of the first surface S3a of the second controller chip 310b, and a second conductive film 320b covering the second contact pad 305b and the second pad 105b of the substrate 101 on the second insulating film 315b. The second controller structure 300B may further include a second adhesive film 325b disposed on the second surface S3b of the second controller chip 310b.

The second chip structure 120B and the second controller structure 300B may be symmetrical with respect to a conceptual axis parallel to the third direction (Z-direction) of the first chip structure 120A and the first controller structure 300A. The description for the first controller structure 300A may also be applied to the second controller structure 300B.

The second controller chip 310b may include a control circuit for the second chip structure 120B. The second controller chip 310b may include a memory controller configured to determine a data processing order of a plurality of memory chips and to limit and/or prevent errors and bad sectors. The second controller chip 310b may be electrically connected to the substrate 101 through a second conductive film 320b connecting the second contact pad 305b to the second pad 105b.

The second controller chip 310b may include a first surface S3a oriented in the first horizontal direction (+X-direction), a second surface S3b oriented in the second horizontal direction (−X-direction) while opposing the first surface S3a, a third surface S4a oriented in the fourth horizontal direction (−Y-direction), and a fourth surface S4b opposing the third surface S4a and oriented in the third horizontal direction (+Y-direction).

A second insulating film 315b covering a lower region disposed below a region in which a second contact pad 305b is disposed on the first surface S3a of the second controller chip 310b and extending to the substrate 101 may be disposed. The second insulating film 315b may extend to a region adjacent to a region in which a second pad 105b is disposed on the substrate 101.

A second conductive film 320b covering the second contact pad 305b of the second controller chip 310b and the second pad 105b of the substrate 101 may be disposed on the second insulating film 315b. The second controller chip 310b and the substrate 101 may be electrically connected to each other through the second conductive film 320b.

The second adhesive film 325b may be disposed on the second surface S3b of the second controller chip 310b. However, an example embodiment thereof is not limited thereto, and the second adhesive film 325b may not be provided.

The encapsulant 150 may protect the first and second chip structures 120A and 120B and the first and second controller structures 300A and 300B from external environments such as physical impact or moisture. The encapsulant 150 may be formed, for example, by curing an epoxy molding compound (EMC).

According to example embodiments, a semiconductor package may include a first chip structure 120A including the plurality of first semiconductor chips a1-a7 having a staircase shape and disposed on the substrate 101 by a desired and/or alternatively predetermined distance, and a first controller chip 310a for controlling the first chip structure 120A, and the first controller chip 310a may be disposed on the substrate 101 in a region overlapping a staircase surface of the first chip structure 120A by the staircase shape. Accordingly, by reducing a mounting area occupied by the first controller chip 310a on the substrate 101, a semiconductor package having increased integration density may be provided.

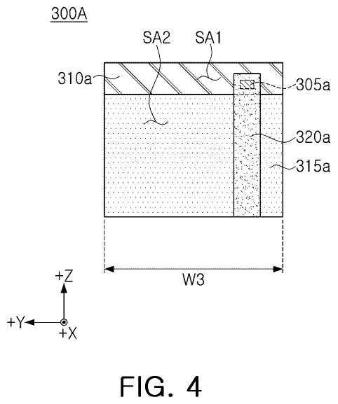

FIG. 4 is a diagram illustrating a first controller structure in FIG. 1 according to an example embodiment, viewed from side. FIG. 4 illustrates the arrangement of the first insulating film 315a and the first conductive film 320a disposed on the first surface S1a of the first controller chip 310a of the first controller structure 300A.

Referring to FIGS. 1, 2, and 4, the first surface S1a of the first controller chip 310a may include an upper region SA1 in which a first contact pad 305a is disposed and a lower region SA2 disposed below the upper region SA1. An area of the upper region SA1 may be smaller than an area of the lower region SA2. The first insulating film 315a may expose the upper region SA1 of the first surface S1a, may cover the lower region SA2 and may extend to the substrate 101. The first conductive film 320a may cover the first contact pad 305a in the upper region SA1 of the first surface S1a, may extend to the first insulating film 315a and the substrate 101 corresponding to a region below the region in which the first contact pad 305a is disposed, and may cover the first pad 105a on the substrate 101. In an example, the first conductive film 320a may be disposed on a first conceptual axis along which the first contact pad 305a of the first controller chip 310a and the first pad 105a of the substrate 101 are disposed. The first conceptual axis may be parallel to the first direction (X-direction).

An area of the first insulating film 315a disposed on the first surface S1a of the first controller chip 310a may be larger than an area of the first conductive film 320a disposed on the first surface S1a of the first controller chip 310a.

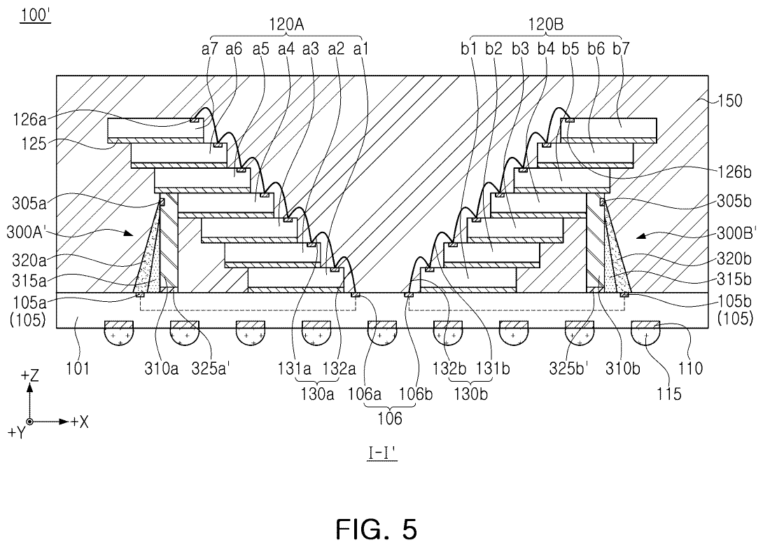

FIG. 5 is a cross-sectional diagram illustrating a semiconductor package taken along line I-I′ according to another example embodiment.

Referring to FIGS. 1 and 5, the components other than the first adhesive film 325a′ of the first controller structure 300A′ and the second adhesive film 325b′ of the second controller structure 300B′ in the semiconductor package 100′ may be the same as or correspond to the components illustrated in FIG. 2. The first adhesive film 325a′ disposed on a lower surface of the first controller chip 310a of the first controller structure 300A′ may further be included. An upper region of the second surface S1b of the first controller chip 310a of the first controller structure 300A′ may be in contact with a side surface of the 1-4 semiconductor chip a4. In an example, the second controller structure 300B′ may further include the second adhesive film 325b′ disposed on a lower surface of the second controller chip 310b. The upper region of the second surface S3b of the second controller chip 310b of the second controller structure 300B may be in contact with a side surface of the 2-4 semiconductor chip b4.

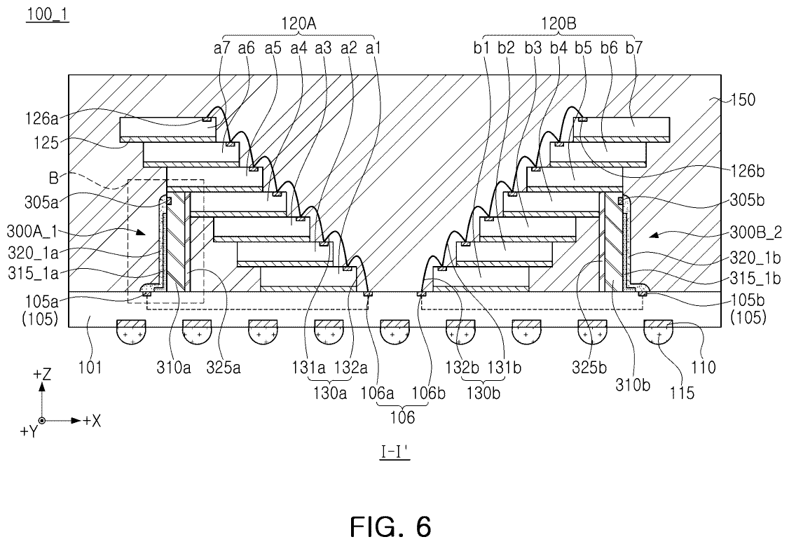

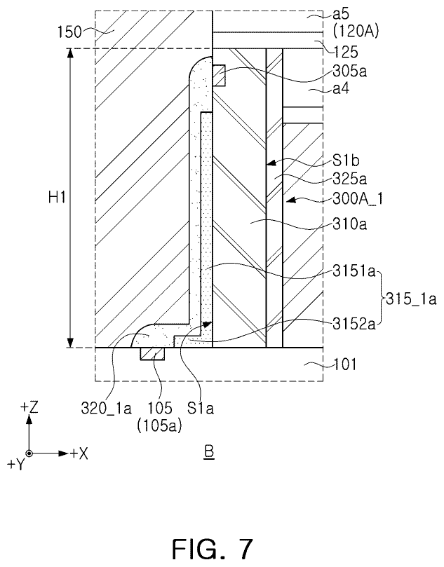

FIG. 6 is a cross-sectional diagram illustrating a semiconductor package taken along line I-I′ according to another example embodiment. FIG. 7 is an enlarged diagram illustrating region B of the semiconductor package illustrated in FIG. 6 according to an example embodiment.

Referring to FIGS. 6 and 7, the components other than the first insulating film 315_1a and the first conductive film 320_1a of the first controller structure 300A_1 and the second insulating film 315_1b and the first conductive film 320_1b of the second controller structure 300B_1 in the semiconductor package 100_1 may be the same as or correspond to the components illustrated in FIG. 2. In an example, the first insulating film 315_1a of the first controller structure 300A_1 and the second insulating film 315_1b of the second controller structure 300B_1 may have a uniform thickness. In an example, the first insulating film 315_1a of the first controller structure 300A_1 and the second insulating film 315_1b of the second controller structure 300B_1 may be film-type insulating films. In an example, the first insulating film 315_1a may include a first portion 3151a disposed on a lower region (e.g., lower region SA2 in FIG. 4) of the first surface S1a of the first controller chip 310a and a second portion 3152a extending from the first portion 3151a and disposed on the substrate 101. In an example, the first portion 3151a and the second portion 3152a of the first insulating film 315_1a may have uniform thicknesses.

The first conductive film 320_1a may cover the first contact pad 305a on the first surface S1a of the first controller chip 310a, may extend to the first insulating film 315_1a and may cover the first pad 105a on the substrate 101. The first conductive film 320_1a disposed on the first insulating film 315_1a may correspond to a surface profile of the first insulating film 315_1a. That is, the first conductive film 320_1a on the first insulating film 315_1a may have a uniform thickness.

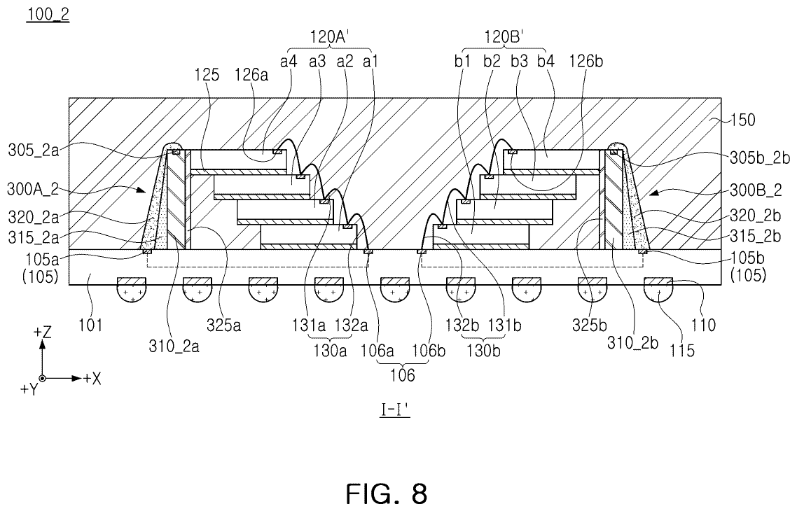

FIG. 8 is a cross-sectional diagram illustrating a semiconductor package according to another example embodiment.

Referring to FIG. 8, the components other than the first and second chip structures 120A′ and 120B′ and the first and second controller structures 300A_2 and 300B_2 in the semiconductor package 100_2 may be the same as or correspond to the components illustrated in FIG. 2.

The semiconductor package 100_2 may include a substrate 101, first and second chip structures 120A′ and 120B′ on the substrate 101, first and second controller structures 300A_2 and 300B_2, and first and second bonding wire structures 130a and 130b for electrically connecting the first and second chip structures 120A′ and 120B′ to the substrate 101. The semiconductor package 100_2 may further include an encapsulant 150 for encapsulating the first and second chip structures 120A′ and 120B′ and the first and second controller structures 300A_2 and 300B_2 on the substrate 101.

The first chip structure 120A′ may include first semiconductor chips a1-a4 having a staircase shape in the first horizontal direction (−X-direction) and stacked in order on the substrate 101. In an example, the second chip structure 120B′ may include second semiconductor chips b1-b4 spaced apart from the first chip structure 120A′ in the second horizontal direction (+X-direction) on the substrate 101 and may have a staircase shape in the second horizontal direction (+X-direction) and stacked in order.

The first controller structure 300A_2 may be disposed on one side of the first chip structure 120A′. That is, the first controller structure 300A_2 may not overlap the first chip structure 120A′ in the third direction (Z-direction). In an example, the second controller structure 300B_2 may be disposed on one side of the second chip structure 120B′. That is, the second controller structure 300_2 may not overlap the second chip structure 120B′ in the third direction (Z-direction).

The first controller structure 300A_2 may include a first controller chip 310_2a having an upper surface on which a first contact pad 305_2a is disposed, a first insulating film 315_2a disposed on one surface (e.g., the first surface S1a in FIG. 1) of the first controller chip 310_2a, and a first conductive film 320_2a covering the first contact pad 305_2a and the first pad 105a of the substrate 101, and extending from an upper surface of the first controller chip 310_2a to side surface of the first insulating film 315_2a and the substrate 101. The first controller structure 300A_2 may further include a first adhesive film 325a disposed on the other surface (e.g., the second surface S1b in FIG. 1) of the first controller chip 310_2a.

The first contact pad 305_2a may be disposed on an upper surface of the first controller chip 310_2a and may be buried in the first controller chip 310_2a. In an example, the first contact pad 305_2a may be electrically connected to the first pad 105a through the first conductive film 320_2a. When viewed on a plane, the first contact pad 305_2a and the first pad 105a may be disposed on a conceptual axis parallel to the first direction (X-direction).

The first insulating film 315_2a may cover one surface (e.g., the first surface S1a in FIG. 1) of the first controller chip 310_2a and may extend to the substrate 101. The first insulating film 315_2a may have a width increasing downwardly in the first direction (X-direction). In an example, the first insulating film 315_2a may completely cover one surface (e.g., the first surface S1a in FIG. 1) of the first controller chip 310_2a.

The first conductive film 320_2a may cover the first contact pad 305_2a and the first pad 105a of the substrate 101 on the upper surface of the first controller chip 310_2a, and may extend to the first insulating film 315_2a and the substrate 101 disposed between the first contact pad 305_2a and the first pad 105a. The first controller chip 310_2a and the substrate 101 may be electrically connected to each other through the first conductive film 320_2a. The first conductive film 320_2a disposed on the first insulating film 315_2a may correspond to a surface profile of the first insulating film 315_2a. The first conductive film 320_2a may have a thickness in the first direction (X-direction) increasing toward the upper surface of the substrate 101.

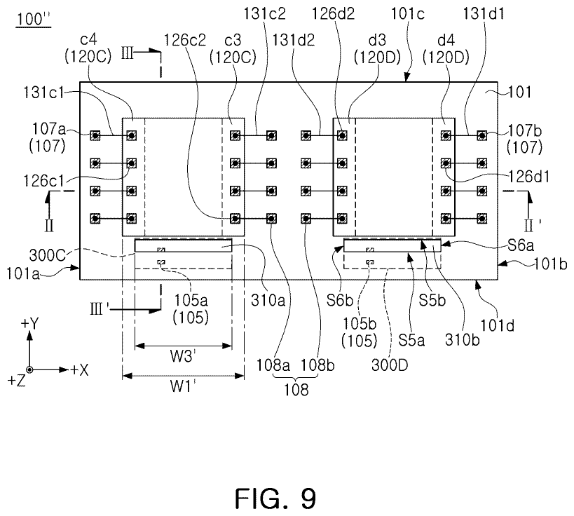

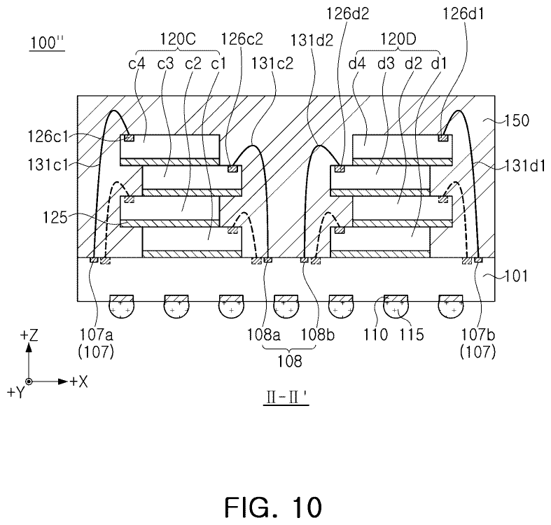

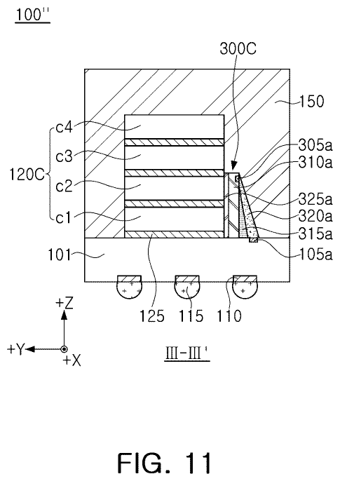

FIG. 9 is a cross-sectional diagram illustrating a semiconductor package according to another example embodiment. FIG. 10 is a cross-sectional diagram illustrating the semiconductor package illustrated in FIG. 9 taken along line II-II′ according to an example embodiment. FIG. 11 is a cross-sectional diagram illustrating the semiconductor package illustrated in FIG. 9 taken along line III-III′ according to an example embodiment.

Referring to FIGS. 9, 10, and 11, a semiconductor package 100″ may include a substrate 101, first bonding wire structures 131c1 and 131c2 for electrically connecting first and second chip structures 120C and 120D, first and second controller structures 300C and 300D and first chip structure 120C on the substrate 101 to the substrate 101, and second bonding wire structures 131d1 and 131d2 for electrically connecting second chip structure 120D to the substrate 101. The semiconductor package 100″ may further include an encapsulant 150 for encapsulating the first and second chip structures 120C and 120D and the first and second controller structures 300C and 300D on the substrate 101.

The substrate 101 may include an upper surface and a lower surface opposing the upper surface. The substrate 101 may be configured as a support substrate on which the first and second chip structures 120C and 120D and the first and second controller structures 300C and 300D are mounted on an upper surface of the substrate 101.

The substrate 101 may include a first side surface 101a adjacent to the first chip structure 120C, a second side surface 101b adjacent to the second chip structure 120D and spaced apart from the first side surface 101a in the second horizontal direction (+X-direction), a third side surface 101c intersecting the first side surface 101a and the second side surface 101b, and a fourth side surface 101d opposing the third side surface 101c. The first side surface 101a and the second side surface 101b may extend in the second direction (Y-direction), and the third side surface 101c and the fourth side surface 101d may extend in the first direction (X-direction).

The substrate 101 may include third and fourth upper pads 107 and 108 disposed on a upper surface and lower pads 110 disposed on a lower surface of the substrate 101. The third and fourth upper pads 107 and 108 may be buried in the substrate 101, and the upper surfaces of the third and fourth upper pads 107 and 108 may be coplanar with the upper surface of the substrate 101.

The third upper pads 107 may include 3-1 upper pads 107a and 3-2 upper pads 107b, and the 3-1 upper pads 107a may be a connection pad for connecting even-numbered first semiconductor chips c2 and c4 of the first chip structure 120C described later to the substrate 101. The 3-2 upper pads 107b may be a connection pad for connecting even-numbered second semiconductor chips d2 and d4 of the second chip structure 120D described later to the substrate 101. The 3-1 upper pads 107a may be disposed between the first side surface 101a of the substrate 101 and the first chip structure 120C, and the 3-2 upper pads 107b may be disposed between the second side surface 101b of the substrate 101 and the second chip structure 120D.

The fourth upper pads 108 may include 4-1 upper pads 108a and 4-2 upper pads 108b, and the 4-1 upper pads 108a may be a connection pad for connecting odd-numbered first semiconductor chips c1 and c3 of the first chip structure 120C to the substrate 101. The 4-2 upper pads 108b may be a connection pad for connecting odd-numbered second semiconductor chips d1 and d3 of the second chip structure 120D to the substrate 101. In an example, the fourth upper pads 108 may be disposed between the first and second chip structures 120C and 120D.

The first chip structure 120C and the second chip structure 120D spaced apart from the first chip structure 120C in the first direction (X-direction) may be disposed on the substrate 101.

The first chip structure 120C may include first semiconductor chips c1-c4 protruding alternately in the first horizontal direction (−X-direction) and the second horizontal direction (+X-direction). In the first chip structure 120C, a 1-1 semiconductor chip c1 protruding in the second horizontal direction (+X-direction) and a 1-2 semiconductor chip c2 protruding in the first horizontal direction (−X-direction) may be disposed alternately. Accordingly, the 1-3 semiconductor chip c3 may protrude in the second horizontal direction (+X-direction), the 1-4 semiconductor chip c4 may protrude in the first horizontal direction (−X-direction). In an example, the 1-2 semiconductor chip c2 may be shifted from an upper surface of the 1-1 semiconductor chip c1 by a first distance in the first horizontal direction (−X direction), the 1-3 semiconductor chip c3 may be shifted from the upper surface of the 1-2 semiconductor chip c2 by the first distance in the second horizontal direction (+X-direction), and the 1-4 semiconductor chip c4 may be shifted from the upper surface of the 1-3 semiconductor chip c3 by the first distance in the first horizontal direction (−X-direction). In an example, the first semiconductor chips c1-c4 of the semiconductor package 100″ may include four chips, but an example embodiment thereof is not limited thereto, and the first semiconductor chips c1-c4 may include five or more chips.

The 1-1 chip pads 126c1 may be disposed on upper surfaces of the 1-2 semiconductor chip c2 and the 1-4 semiconductor chip c4, even-numbered semiconductor chips among the first semiconductor chips c1-c4.

The 1-2 chip pads 126c2 may be disposed on the upper surfaces of 1-1 semiconductor chip c1 and the 1-3 semiconductor chip c3, odd-numbered semiconductor chips among the first semiconductor chips c1-c4.

The first bonding wire structures 131c1 and 131c2 may include 1-1 bonding wires 131c1 and 1-2 bonding wires 131c2. The 1-1 bonding wires 131c1 may connect the 1-1 chip pads 126c1 to the 3-1 upper pads 107a of the first semiconductor chips c1-c4. The 1-2 bonding wires 131c2 may connect the 1-2 chip pads 126c2 and the 4-1 upper pads 108a of first semiconductor chips c1-c4 to each other.

The second chip structure 120D may include second semiconductor chips d1-d4 protruding alternately in the first horizontal direction (−X-direction) and the second horizontal direction (+X-direction). The second chip structure 120D may be disposed alternately with the 2-1 semiconductor chip d1 protruding in the first horizontal direction (−X-direction) and the 2-2 semiconductor chip d2 protruding in the second horizontal direction (+X-direction). Accordingly, the 2-3 semiconductor chip d3 may protrude in the first horizontal direction (−X-direction), and the 2-4 semiconductor chip d4 may protrude in the first horizontal direction (+X-direction). In an example, the 2-2 semiconductor chip d2 may be shifted from the upper surface of the 2-1 semiconductor chip d1 by the first distance in the second horizontal direction (+X-direction), the 2-3 semiconductor chip d3 may be shifted from the upper surface of the 2-2 semiconductor chip d2 by the first distance in the first horizontal direction (−X-direction), and the 2-4 semiconductor chip d4 may be shifted from the upper surface of the 2-3 semiconductor chip d3 by the first distance in the second horizontal direction (+X-direction). In an example, the second semiconductor chips d1-d4 of the semiconductor package 100″ may include four chips similarly to the first semiconductor chips c1-c4, but an example embodiment thereof is not limited thereto, and the second semiconductor chips d1-d4 may include more than five chips.

The 2-1 chip pads 126d1 may be disposed on upper surfaces of the 2-2 semiconductor chip d2 and the 2-4 semiconductor chip d4, even-numbered semiconductor chips among the second semiconductor chips d1-d4.

The 2-2 chip pads 126d2 may be disposed on upper surfaces of the 2-1 semiconductor chip d1 and the 2-3 semiconductor chip d3, odd-numbered semiconductor chips among the second semiconductor chips d1-d4.

The second bonding wire structures 131d1 and 131d2 may include 2-1 bonding wires 131d1 and 2-2 bonding wires 131d2. The 2-1 bonding wires 131d1 may connect the 2-1 chip pads 126d1 to the 3-2 upper pads 107b of the second semiconductor chips d1-d4. The 2-2 bonding wires 131d2 may connect the 2-2 chip pads 126d2 to the 4-2 upper pads 108b of the second semiconductor chips d1-d4.

The semiconductor package 100″ may include a first controller structure 300C in contact with the first chip structure 120C on the substrate 101, a second chip structure 120D and in contact with the second controller structure 300D, and first upper pads 105 disposed on the substrate 10 and electrically connected to the first and second controller structures 300C and 300D. The first upper pads 105 may include first and second pads 105a and 105b. The first pad 105a may be a connection pad for connecting the first controller structure 300C to the substrate 101, and the second pad 105b may be a connection pad for connecting the second controller structure 300D to the substrate 101. In an example, the first and second pads 105a and 105b may be spaced apart from each other in the first direction (X-direction).

The first controller structure 300C may be in contact with one surface of the first chip structure 120C adjacent to the fourth side surface 101d of the substrate 101 on the substrate 101. The second controller structure 300D may be in contact with one surface of the second chip structure 120D adjacent to the fourth side surface 101d of the substrate 101 on the substrate 101.

The first controller structure 300C may include a first controller chip 310a having a first surface S5a on which a first contact pad 305a is disposed, a first insulating film 315a disposed on a portion of the first surface S5a of the first controller chip 310a, and a first conductive film 320a covering the first contact pad 305a and the first pad 105a of the substrate 101 on the first insulating film 315a. The first controller structure 300C may further include a first adhesive film 325a disposed on a second surface S5b of the first controller chip 310a.

The second controller structure 300D may be spaced apart from the first controller structure 300C in the second horizontal direction (+X-direction) and may have the same structure as the first controller structure 300C.

The first and second controller chips 310a and 310b may include a first surface S5a directed to the fourth side surface 101d and on which the first and second contact pads 305a and 305b are disposed, a second surface S5b opposing the first surface S5a and directed to the third side surface 101c, a third surface S6a directed to the second side surface 101b, and a fourth surface S6b opposing the third surface S6a and directed to the first side surface 101a. In an example, an area of each of the first surface S5a and the second surface S5b may be larger than an area of a lower surface and a upper surface of each of the third surface S6a, the fourth surface S6b, of the first and second controller chips 310a and 310b.

Each of the first and second controller chips 310a and 310b may have a first horizontal length W3′ in the first direction (X-direction), and the first horizontal length W3′ may be smaller than the length W1′ in the first direction (X-direction) of each of the first and second chip structures 120C and 120D. However, but an example embodiment thereof is not limited thereto, and in another example, the first horizontal length W3′ of each of the first and second controller chips 310a and 310b may be substantially equal to the length W1′ in the first direction (X-direction) of each of the first and second chip structures 120C and 120D.

The first insulating film 315a may cover a lower region disposed below a region in which a first contact pad 305a is disposed on the first surface S5a of the first controller chip 310a, and may extend to the substrate 101. The first contact pad 305a of the first surface S5a and the first pad 105a of the substrate 101 may be exposed from the first insulating film 315a. In an example, the first insulating film 315a may have a width increasing downwardly in the second direction (Y-direction).

The first conductive film 320a may cover the first contact pad 305a of the first controller chip 310a and the first pad 105a of the substrate 101 on the first insulating film 315a. The first conductive film 320a may cover the first contact pad 305a on the first surface S5a of the first controller chip 310a, may extend to the first insulating film 315a and the substrate 101 and may cover the first pad 105a on the substrate 101. The first conductive film 320a may have a thickness in the second direction (Y-direction) increasing toward the upper surface of the substrate 101.

The first adhesive film 325a may be disposed on the second surface S5b of the first controller chip 310a. However, an example embodiment thereof is not limited thereto, and the first adhesive film 325a may not be provided. In an example, the first adhesive film 325a may be in contact with side surfaces of the 1-1 semiconductor chip c1 and the 1-2 semiconductor chip c2.

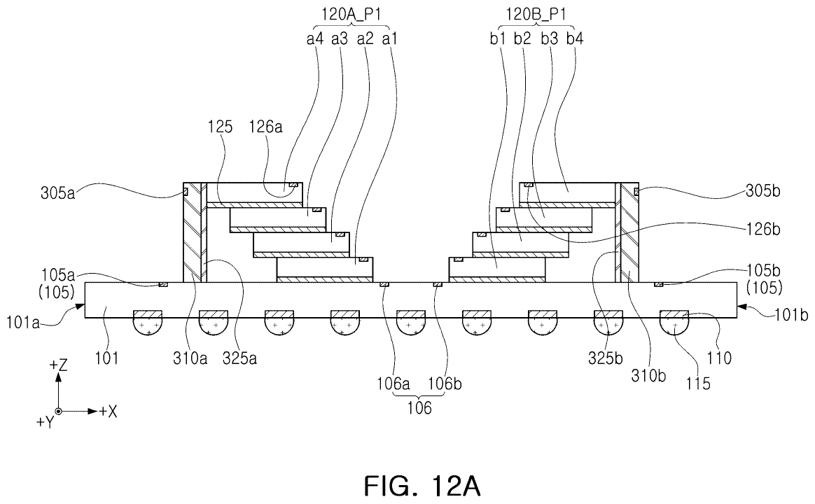

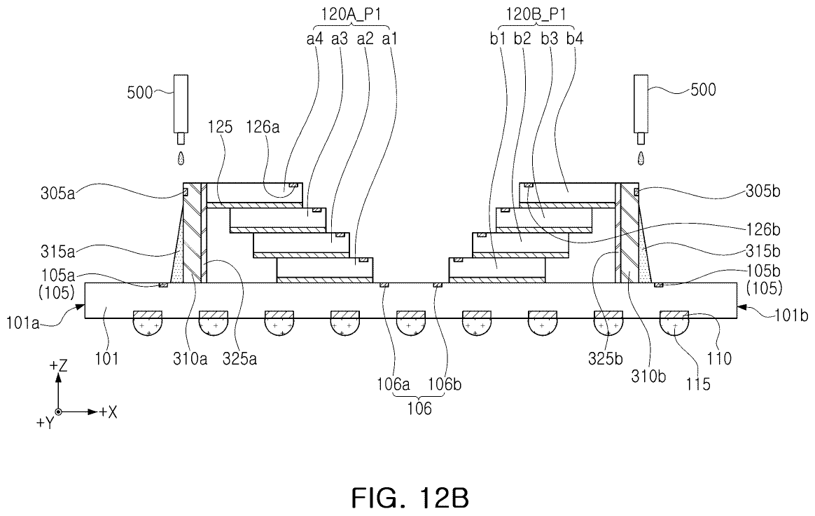

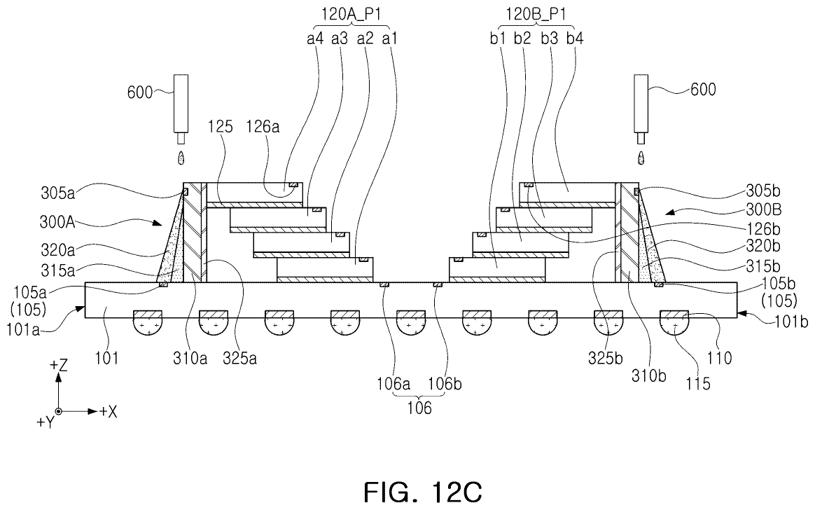

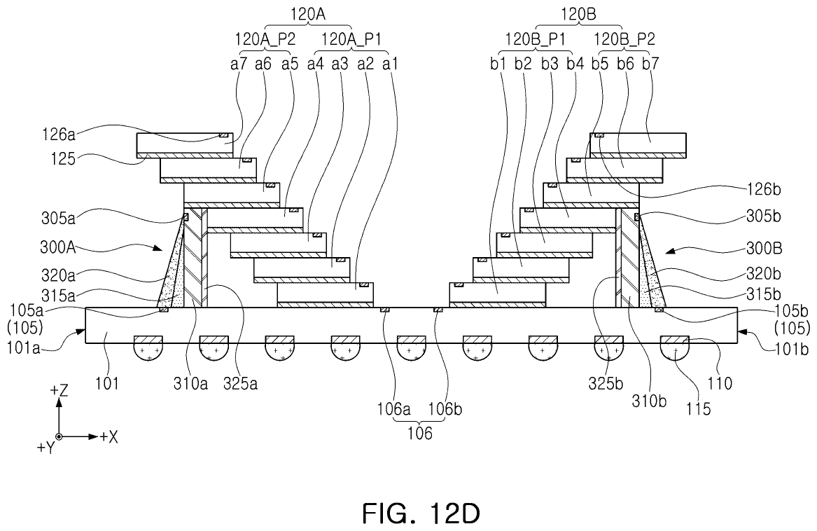

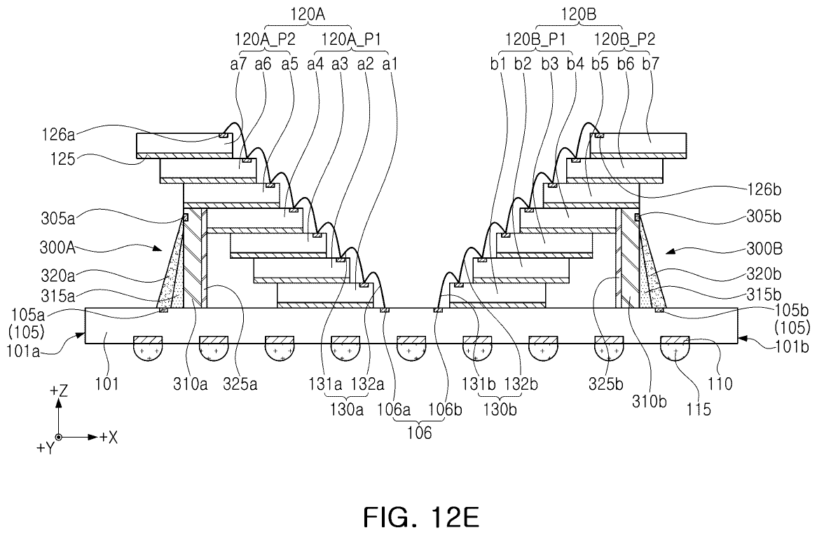

FIGS. 12A to 12E are cross-sectional diagrams illustrating a semiconductor package according to an example embodiment.

Referring to FIG. 12a, a method for manufacturing a semiconductor package may include a process of preparing a substrate 101 having an upper surface on which first and second upper pads 105 and 106 are disposed and a lower surface on which lower pads 110 are disposed, a process of forming a first lower chip structure 120A_P1 and a second lower chip structure 120B_P1 on the upper surface of the substrate 101, a process of forming a first controller chip 310a in which a first contact pad 305a is disposed on one side of the first lower chip structure 120A_P1, and having one surface adjacent to the first side surface 101a of the substrate 101, and a process of forming a second controller chip 310b in which a second contact pad 305b is disposed on one side of the second lower chip structure 120B_P1, and having one surface adjacent to the second side surface 101b of the substrate 101.

In the process of preparing the substrate 101, the first upper pads 105 for connecting to the first and second controller chips 310a and 310b may be formed on an upper surface of the substrate 101 and the second upper pads 106 for connecting to the first lower chip structure 120A_P1 and the second lower chip structure 120B_P1 may be formed between the first upper pads 105 of the substrate 101.

The process of forming the first lower chip structure 120A_P1 and the second lower chip structure 120B_P1 on the upper surface of the substrate 101 may include a process of forming the first lower chip structure 120A_P1 and a process of forming the second lower chip structure 120B_P1 spaced apart from the first lower chip structure 120A_P1 in the second horizontal direction (+X-direction).

In the process of forming the first lower chip structure 120A_P1, a 1-1 semiconductor chip a1, a 1-2 semiconductor chip a2, a 1-3 semiconductor chip a3, and a 1-4 semiconductor chip a4 may be formed in order on the substrate 101 and may be shifted from each other by a desired and/or alternatively predetermined distance in the first horizontal direction (−X-direction). Each of the 1-1 semiconductor chip a1, the 1-2 semiconductor chip a2, the 1-3 semiconductor chip a3, and the 1-4 semiconductor chip a4 may be fixed through an adhesive film 125 disposed on the lower surface of each of the 1-1 semiconductor chip a1, the 1-2 semiconductor chip a2, the 1-3 semiconductor chip a3, and the 1-4 semiconductor chip a4. First chip pads 126a disposed on upper surfaces of the 1-1 semiconductor chip a1, the 1-2 semiconductor chip a2, the 1-3 semiconductor chip a3, and the 1-4 semiconductor chip a4, respectively, may be exposed.

In the process of forming the second lower chip structure 120B_P1, the 2-1 semiconductor chip b1, the 2-2 semiconductor chip b2, the 2-3 semiconductor chip b3, and the 2-4 semiconductor chip d4 may be disposed in order on the substrate 101 and may be shifted from each other by a desired and/or alternatively predetermined distance in the second horizontal direction (+X-direction). Each of the 2-1 semiconductor chip b1, the 2-2 semiconductor chip b2, the 2-3 semiconductor chip b3, and the 2-4 semiconductor chip d4 may be fixed through an adhesive film 125 disposed on the lower surface of each of the 2-1 semiconductor chip b1, the 2-2 semiconductor chip b2, the 2-3 semiconductor chip b3, and the 2-4 semiconductor chip d4. The second chip pads 126b disposed on the upper surfaces of the 2-1 semiconductor chip b1, the 2-2 semiconductor chip b2, the 2-3 semiconductor chip b3, and the 2-4 semiconductor chip d4, respectively, may be exposed.

In the process in which the first controller chip 310a is disposed, the first controller chip 310a may be disposed on one side of the first lower chip structure 120A_P1 such that the first adhesive film 325a may be formed on the other surface (e.g., second surface S1b in FIG. 1) of the first controller chip 310a to oppose the first lower chip structure 120A_P1. The first controller chip 310a may be disposed such that one surface of the first controller chip 310a on which the first contact pad 305a is disposed may be directed to the first side surface 101a of the substrate 101.

In the process in which the second controller chip 310b is disposed, while the second adhesive film 325b is formed on the other surface (e.g., the second surface S3b in FIG. 1) of the second controller chip 310b, the second controller chip 310b may be disposed on one side of the second lower chip structure 120B_P1 such that the second adhesive film 325b may oppose the second lower chip structure 120B_P1. The second controller chip 310b may be disposed such that one surface of the second controller chip 310b on which the second contact pad 305b is disposed may be directed to the second side surface 101b of the substrate 101.

Referring to FIG. 12B, a method for manufacturing a semiconductor package may include a process of forming a first insulating film 315a on one surface of a first controller chip 310a and a process of forming a second insulating film 315b on one surface of a second controller chip 310b. The first insulating film 315a and the second insulating film 315b may be formed by an insulating material discharged to one surface of the first controller chip 310a and one surface of the second controller chip 310b through a first printing device 500. The first printing device 500 may operate in an ink-jet manner or a printing manner. However, but an example embodiment thereof is not limited thereto, and in another example, the first insulating film 315a and the second insulating film 315b may be formed by being attached to one surface of the first controller chip 310a and one surface of the second controller chip 310b in the form of film.

To form the first insulating film 315a, the first printing device 500 may be disposed on one surface of the first controller chip 310a, and the first printing device 500 may be controlled to move in the second direction (Y-direction) such that the first contact pad 305a may be exposed, and the insulating material may be discharged to a lower region below the region in which the first contact pad 305a is disposed through the first printing device 500. The first insulating film 315a may extend to a region adjacent to the region in which the first pad 105a is formed on the substrate 101. The second insulating film 315b may be formed in the same manner as the first insulating film 315a. The first insulating film 315a and the second insulating film 315b may be formed such that the insulating material may be stacked downwardly and the thickness in the first direction (X-direction) may increase.

Referring to FIG. 12C, the method for manufacturing a semiconductor package may include a process of forming a first conductive film 320a on the first insulating film 315a to cover the first contact pad 305a of the first controller chip 310a and the first pad 105a on the substrate 101, and a process of forming a second conductive film 320b on the second insulating film 315b to cover the second contact pad 305b of the second controller chip 310b and the second pad 105b on the substrate 101.

In the process of forming the first conductive film 320a and the second conductive film 320b, the first conductive film 320a and the second conductive film 320b may be formed through a conductive material discharged to the first and second insulating films 315a and 315b through a second printing device 600. To form the first conductive film 320a, the second printing device 600 may be disposed in an upper portion of the region in which the first insulating film 315a is disposed, the second printing device 600 may be controlled to move in the second direction (Y-direction) so as to cover the first contact pad 305a disposed on one surface of the first controller chip 310a, and a conductive material may be printed to cover the first contact pad 305a and the first pad 105a through the second printing device 600. The second conductive film 320b may be formed in the same manner as the first conductive film 320a. The first conductive film 320a may be formed to cover the first contact pad 305a and the first pad 105a, and may correspond to a surface profile of the first insulating film 315a on the first insulating film 315a. As the first conductive film 320a and the second conductive film 320b are formed, first and second controller structures 300A and 300B may be manufactured on the substrate 101.

Referring to FIG. 12D, the method for manufacturing a semiconductor package may include a process of forming a first upper chip structure 120A_P2 on the first controller structure 300A and the first lower chip structure 120A_P1 and a process of forming a second upper chip structure 120B_P2 on the second controller structure 300B and the second lower chip structure 120B_P1.

In the process of forming the first upper chip structure 120A_P2, a 1-5 semiconductor chip a5, a 1-6 semiconductor chip a6, and a 1-7 semiconductor chip a7 may be formed in order on the first lower chip structure 120A_P1 and may be shifted by a desired and/or alternatively predetermined distance in the first horizontal direction (−X-direction). First chip pads 126a disposed on upper surfaces of the 1-5 semiconductor chip a5, the 1-6 semiconductor chip a6, and the 1-7 semiconductor chip a7, respectively, may be exposed. As the first upper chip structure 120A_P2 is formed on the first lower chip structure 120A_P1, the first chip structure 120A may be manufactured.

In the process of forming the second upper chip structure 120B_P2, a 2-5 semiconductor chip b5, a 2-6 semiconductor chip b6, and a 2-7 semiconductor chip b7 may be formed in order on the second lower chip structure 120B_P1 and may be shifted by a desired and/or alternatively predetermined distance in the second horizontal direction (+X-direction). The second chip pads 126b disposed on upper surfaces of the 2-5 semiconductor chip b5, the 2-6 semiconductor chip b6, and the 2-7 semiconductor chip b7, respectively, may be exposed. As the second upper chip structure 120B_P2 is formed on the second lower chip structure 120B_P1, the second chip structure 120B may be manufactured.

Referring to FIG. 12E, the method for manufacturing a semiconductor package may include a process of forming a first bonding wire structure 130A connecting the first semiconductor chips a1-a7 to the substrate 101 and a process of forming a second bonding wire structure 130B connecting the second semiconductor chips b1-b7 to the substrate 101.

In the process of forming the first bonding wire structure 130A, a first upper wire structure 131a connecting first chip pads 126a to each other may be formed to electrically connect the first semiconductor chips a1-a7 to each other, and a first lower wire structure 132a connecting the first chip pad 126a to the third pad 106a of the 1-1 semiconductor chip a1 may be formed.

In the process of forming the second bonding wire structure 130B, the second upper wire structure 131b connecting the second chip pads 126b to each other to electrically connect the second semiconductor chips b1-b7 to each other may be formed, and the second lower wire structure 132b connecting the second chip pad 126b to the fourth pad 106b of the 2-1 semiconductor chip b1 may be formed.

Thereafter, referring to FIG. 2 and FIG. 12E, the method of manufacturing the semiconductor package may form an encapsulant 150 for encapsulating the first and second chip structures 120A and 120B and the first and second controller structures 300A and 300B on the substrate 101. Accordingly, the semiconductor package 100 in FIGS. 1 to 4 may be manufactured.

According to the aforementioned example embodiments, a semiconductor package may include a controller chip extending vertically from an upper surface of the substrate to one side of an intermediate memory chip among memory chips on the substrate. Accordingly, the mounting area occupied by the controller chip on the substrate may be reduced, such that the semiconductor package having improved integration density may be provided.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While example embodiments have been illustrated and described above, it will be configured as apparent to those skilled in the art that modifications and variations could be made without departing from the scope of inventive concepts as defined by the appended claims.

What is claimed is:

1. A semiconductor package, comprising:
a substrate including a first pad and a second pad spaced apart from each other on an upper surface of the substrate;
a first chip structure including first semiconductor chips stacked in order on the substrate and having a staircase shape in a first horizontal direction, the first semiconductor chips including a first intermediate semiconductor chip having an upper surface spaced apart from the upper surface of the substrate by a first height;
a second chip structure including second semiconductor chips stacked in order on the substrate to have a staircase shape in a second horizontal direction, the second horizontal direction being opposite the first horizontal direction, the second semiconductor chips including a second intermediate semiconductor chip having an upper surface spaced apart from the upper surface of the substrate by the first height; and
a first controller structure on a first side surface of the first intermediate semiconductor chip, wherein
the first controller structure includes a first controller chip, a first insulating film, and a first conductive film,
a first surface of the first controller chip faces the first horizontal direction and includes a first contact pad disposed thereon,
a second surface of the first controller chip is opposite the first surface of the first controller chip,
the first insulating film extends along the first surface of the first controller chip to the substrate and exposes the first contact pad, and
the first conductive film is on the first insulating film and covers the first contact pad of the first controller chip and the first pad of the substrate.

2. The semiconductor package of claim 1,
wherein the first controller chip has a first length in the first horizontal direction and a second length from the upper surface of the substrate to an upper surface of the first controller chip, and
wherein the second length is greater than the first length.

3. The semiconductor package of claim 2, wherein the second length is equal to or less than the first height.

4. The semiconductor package of claim 2,
wherein the first semiconductor chips are shifted from each other by a first distance in the first horizontal direction, and
wherein the first length is smaller than the first distance.

5. The semiconductor package of claim 1, wherein
as a level in the first conductive film changes downwardly, a width of the first conductive film in the first horizontal direction.

6. The semiconductor package of claim 1, wherein
as a level in the first insulating film changes downwardly, a width of the first insulating film increases in the first horizontal direction.

7. The semiconductor package of claim 1,
wherein a first portion of the first insulating film is on the first surface of the first controller chip,
wherein a second portion of the first insulating film extends from the first portion of the first insulating film and is on the substrate, and
wherein the first portion and the second portion have equal thicknesses.

8. The semiconductor package of claim 1, wherein, when viewed on a plane, the first pad and the first contact pad are on a first conceptual axis and the first conceptual axis is parallel to the first horizontal direction.

9. The semiconductor package of claim 1, wherein the first controller structure further includes a first adhesive film on the second surface of the first controller chip.

10. The semiconductor package of claim 1,
wherein the first semiconductor chips include first upper semiconductor chips disposed in order on the first intermediate semiconductor chip so as to have the staircase shape in the first horizontal direction,
wherein a first uppermost semiconductor chip in an uppermost portion of the first upper semiconductor chips overlaps the first controller structure in a vertical direction, and
wherein the vertical direction intersects the first horizontal direction and the second horizontal direction.

11. The semiconductor package of claim 1, wherein
a third length of the first conductive film is smaller than a fourth length of the first controller chip in a third horizontal direction, and
the third horizontal direction intersects the first horizontal direction and the second horizontal direction.

12. The semiconductor package of claim 11, wherein
the first insulating film has a fifth length in the third horizontal direction, and
the fifth length is greater than the third length.

13. The semiconductor package of claim 1, further comprising:
a second controller structure on a second side surface of the second intermediate semiconductor chip in the second horizontal direction, wherein the second controller structure includes a second controller chip, a second insulating film, and a second conductive film,
a first surface of the second controller chip faces the second horizontal direction and includes a second contact pad disposed thereon,
a second surface of the second controller chip is opposite the first surface of the second controller chip,
the second insulating film extends along the first surface of the second controller chip to the substrate and exposes the second contact pad, and
the second conductive film is on the second insulating film and covers the second contact pad of the second controller chip and the second pad of the substrate.

14. A semiconductor package, comprising:
a substrate including an upper surface including a first upper pad;
first semiconductor chips stacked in order on the substrate; and
a first controller structure in contact with a side surface of at least one semiconductor chip among the first semiconductor chips, wherein the first controller structure includes a first controller chip, a first insulating film, and a first conductive film,
a first surface of the first controller chip faces a first horizontal direction and includes a first contact pad disposed thereon,
a second surface of the first controller chip is opposite the first surface of the first controller chip,
the first insulating film exposes the first contact pad and extends along the first surface of the first controller chip to the substrate, and
the first conductive film is on the first insulating film and covers the first contact pad of the first controller chip and the first upper pad of the substrate.

15. The semiconductor package of claim 14, wherein
an upper region of the first surface of the first controller chip is where the first contact pad is disposed,
a lower region of the first surface of the first controller chip is region below the upper region of the first surface of the first controller chip,
the first insulating film exposes the upper region of the first surface of the first controller chip, and
the first insulating film covers the lower region of the first surface of the first controller chip.

16. The semiconductor package of claim 14, wherein
the first semiconductor chips include a first chip and a second chip alternately disposed in a vertical direction,
the first chip protrudes in a 2-1 horizontal direction,
the second chip protrudes in a 2-2 horizontal direction,
the 2-1 horizontal direction intersects the first horizontal direction, and
the 2-2 horizontal direction is opposite the 2-1 horizontal direction.

17. The semiconductor package of claim 16, wherein the first controller structure is in contact with a side surface of the first chip facing the first horizontal direction and a side surface of the second chip facing the first horizontal direction.

18. The semiconductor package of claim 14, wherein
as a level in the first controller structure changes downwardly, a width of the first insulating film increases in the first horizontal direction and a width of the first conductive film increases in the first horizontal direction.

19. A semiconductor package, comprising:
a substrate having a first side surface, a second side spaced apart from the first side surface in a horizontal direction, and an upper surface including a first pad disposed thereon;
first semiconductor chips stacked in order on the substrate so as to have a staircase shape adjacent to the first side surface; and
a first controller structure on the substrate and overlapping a portion of the first semiconductor chips in a vertical direction, the vertical direction intersecting the horizontal direction, wherein
the first controller structure includes a first controller chip, a first insulating film, and a first conductive film,
the first controller chip extends perpendicular to the upper surface of the substrate,
a first surface of the first controller chip is adjacent to the first side surface of the substrate and includes a first contact pad disposed thereon,
a second surface of the first controller chip is opposite the first surface of the first controller chip,
the first insulating film extends onto the substrate from a location of the first surface of the first controller chip that is below the first contact pad, and
the first conductive film is on the first insulating film and covers the first contact pad and the first pad of the substrate.

20. The semiconductor package of claim 19,
wherein the first pad overlaps the first controller structure in the vertical direction, and
wherein the first pad and the first contact pad are disposed on a conceptual axis parallel to the horizontal direction.
